(19) United States
(12) Patent Application Publication
(10) Pub. No.: US 2001/0000355 A1
(43) Pub. Date: Apr. 19, 2001

(54) Electronic trip unit having software download capabilities

(76) Inventors: Esteban Santos, Farmington, CT (US); Richard Baertsch, Scotia, NY (US); David Fletcher, Simsbury, CT (US)

Correspondence Address: Philmore H. Colburn II, Cantor Colburn LLP, 55 Griffin Road South, Bloomfield, CT, 06002, US

(21) Appl. No.: 09/727,880

(22) Filed: Dec. 1, 2000

Related U.S. Application Data
(63) Continuation-in-part of application No. 09/221,243, filed on Dec. 28, 1998.

(51) Int. Cl. G01R 31/00

(52) U.S. Cl. 702/58; 702/64

(57) ABSTRACT

A trip unit is provided with non-volatile memory, such as EEPROM (Electrically Erasable Programmable Read Only Memory) or Flash memory, for storing the firmware, including initializing parameters, boot code, and operational parameters. This configuration enables one to change the trip unit's firmware after it is manufactured. The present invention provides thus increased functionality to trip units by enabling upgrades and servicing of the trip unit by downloading replacement firmware to it. This would include remotely downloading firmware when the electronic trip unit is connected to a host controller, such as a multi-purpose computer either directly, over the telephone lines, LAN or any other suitable connection such as the Internet.

### RELATED APPLICATIONS

1. This application is a continuation-in-part of U.S. patent application Ser. No. 09/221,243 filed Dec. 28, 1998, which is incorporated by reference herein.

### BACKGROUND OF THE INVENTION

2. The present invention relates generally to electronic trip units. More specifically, the present invention relates to electronic trip units having software download capabilities.

3. Electronic trip units (trip units) for actuating the separable contacts in a circuit breaker are well known. An electronic trip unit typically comprises voltage and current sensors that provide analog signals indicative of the power line signals. The analog signals are converted by an A/D (analog/digital) converter to digital signals that are processed by a microcontroller. The trip unit further includes RAM (random access memory), ROM (read only memory) and EPROM (electronic programmable read only memory) all of which interface with the microcontroller. The ROM includes trip unit application code, e.g., main functionality firmware, including initializing parameters, boot code, and operational parameters. Operational parameters for the application code are also stored in the EPROM. An output of the electronic trip unit actuates separable contacts of the circuit breaker. When the contacts open, circuit current is prevented from flowing from one contact member to the other and therefore, circuit current is prevented from flowing to a load which is connected to the breaker. The electronic trip unit initiates a trip for instantaneous, short time, long time, ground fault and manual conditions.

4. The inventors have discovered a need in the industry for upgradeable or adjustable trip units and have found that the use of EPROM technology has prevented trip units from being upgradeableCa desirable feature to drive service growth in the trip control industry.

### BRIEF SUMMARY OF THE INVENTION

5. To overcome the limitations of the prior art, non-volatile memory such as EEPROM (Electrically Erasable Programmable Read Only Memory) or Flash memory is provided in the trip unit for storing the firmware, enabling one to change the trip unit's firmware after it is manufactured. The present invention provides increased functionality to trip units by enabling upgrades and servicing of the trip unit by downloading firmware to it. This would include remotely downloading firmware when the electronic trip unit is connected to a host controller, such as a multi-purpose computer either directly, over the telephone lines, LAN or any other suitable connection such as the Internet.

6. The above discussed and other features and additional advantages of the present invention will be appreciated and understood by those skilled in the art from the detailed description and drawings.

### BRIEF DESCRIPTION OF THE DRAWINGS

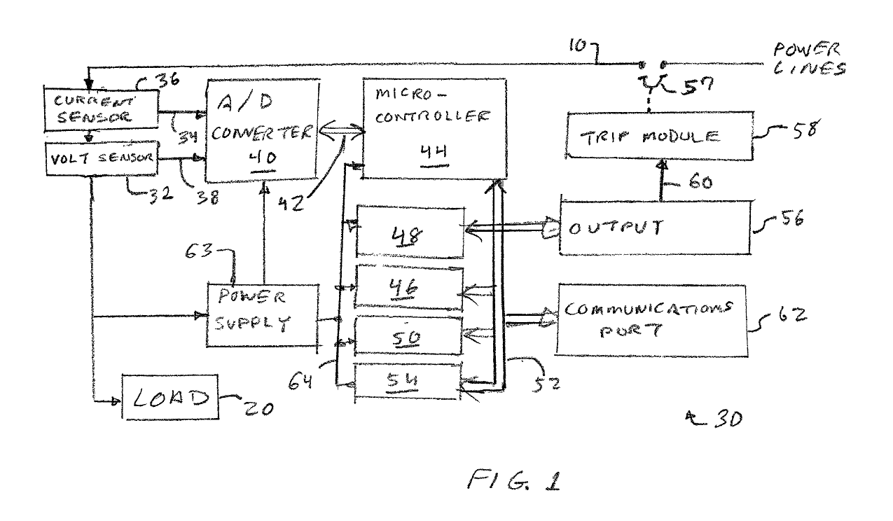

7. FIG. 1 is a schematic block diagram of an electronic trip unit of the present invention; and

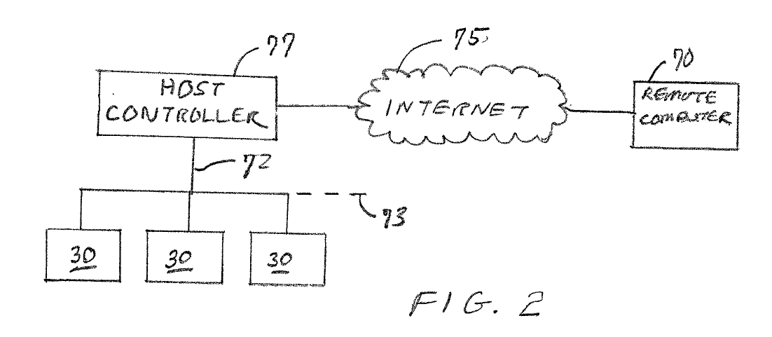

8. FIG. 2 is a schematic block diagram showing the trip unit's interconnectivity with a host controller and server via the Internet.

### DETAILED DESCRIPTION OF THE INVENTION

9. Copending U.S. patent application Ser. No. 09/221,243 filed Dec. 28, 1998, is hereby incorporated in full herein by reference.

10. Referring to FIG. 1, a general schematic of an electronic trip unit of the present invention is generally shown at 30. Power passes along power lines 10 to load 20. Circuit breaker contacts 57, shown in the open position are normally in the closed position so that power can pass to load 20. Voltage sensor 32 and current sensor 36 provide analog signals indicative of a voltage and current measurements on signal lines 38 and 34, respectively. The invention is not limited to requiring that both voltage and current sensors be present, but instead contemplates that either type of sensor, or any other sensor capable of sensing a fault condition of load 20 may be employed.

11. The analog signals on lines 34 and 38 are presented to an A/D (analog/digital) converter 40, which converts these analog signals to digital signals. The digital signals are transferred over datapath 42 to a microcontroller (microprocessor or signal processor) 44, such being commercially available from the Hitachi Electronics Components Group (Hitachi s H8/300 family of microcontrollers). Trip unit 30 further includes RAM (random access memory) 46, ROM (read only memory) 48 and EEPROM (electronic erasable programmable read only memory) or flash memory (including sector erasable flash memory) 50 all of which communicate with the microcontroller 44 over a control bus 52. It will be appreciated that A/D converter 40, ROM 48, RAM 46, or any combination thereof may be internal to microcontroller 44, as is well known. EEPROM 50 is non-volatile so that system information and programming will not be lost during a power interruption or outage. Data, typically status of the circuit breaker, is displayed by a display 54 in response to display signals received from microcontroller 44 over control bus 52. An output control device 56, in response to control signals received from microcontroller 44 over control bus 52, controls a trip module 58 via a line 60.

12. The EEPROM or flash memory includes trip unit application code and software settings, including initializing parameters, operational parameters such as the trip curve, and boot code. The firmware is initially stored in the electronic trip unit at the factory and can be downloaded or flashed for firmware upgrades and servicing. This would include remotely downloading the firmware when the electronic trip unit is connected to a system computer (not shown), either directly, over the telephone lines, or any other suitable connection. It may also be preferred that EEPROM 50 comprises a flash memory whereby such data is flashed, as is well known. During boot up of the electronic trip unit the firmware stored in the EEPROM, in particular the executable code, is loaded into the working memory, i.e., the RAM. This allows the processor to continue operating while the EEPROM or Flash is being updated. The firmware defines trip unit operation, including trip curve characteristics such as instantaneous, short time, long time, ground fault trip.

13. FIG. 2 shows an exemplary embodiment for downloading firmware to trip unit 30. In this embodiment, multiple trip units 30 are connected via local area network 72 to host controller 77 which may be configured for monitoring the status of the trip units 30. Additional trip units (not shown) may be connected using connections 73. Host controller 77 is capable of downloading firmware to trip units 30 directly by the end users, or at the direction of remote computer 70 via the Internet 75. In this configuration, remote computer 70 can also be configured to monitor the trip units' status which can permit a centralized or outsourced monitoring of the industrial systems and also allows servicing of trip units 30 by persons in a remote location, which can reduce down time and expense necessary to get expert personnel to the location when servicing is required.

14. While preferred embodiments have been shown and described, various modifications and substitutions may be made thereto without departing from the spirit and scope of the invention. Accordingly, it is to be understood that the present invention has been described by way of illustrations and not limitation.

What is claimed is:

1. A trip unit comprising:
at least one sensor for sensing at least one condition of a power line providing electricity to a load;
a signal converter for converting signals generated by said sensors into at least one digital value indicative of said at least one condition;
a micro-controller adapted to access said at least one digital value; and
a trip module for separating separable contacts connected in series on said power line, said trip module responsive to a trip signal generated by an output of said micro-controller;
said micro-controller including non-volatile memory for storing micro-controller firmware and a communications port;
said microcontroller being capable of receiving new firmware from a remote location via said communications port and replacing said firm ware stored in said non-volatile memory.

2. The trip unit of claim 1 wherein said communications port is connected to said host controller via a local area network.

3. The trip unit of claim 2 wherein said host controller is programmed for monitoring said trip unit.

4. The trip unit of claim 2 wherein said host controller is connected via an Internet connection to a remote computer such that said remote computer is capable of monitoring said trip unit.

5. The trip unit of claim 2 wherein said host controller is programmed to download firmware to said trip unit.

6. The trip unit of claim 2 wherein said host controller is connected via an Internet connection to a remote computer such that said remote computer is capable of downloading firmware to said trip unit.

7. A circuit breaker comprising:
a set of contacts for making and breaking an electrical connection between an electrical load and an electrical power supply and a
trip unit comprising:
at least one sensor for generating a signal representative at least one condition of a load;
a signal converter converting each of said at least one signal into a corresponding digital value representing a corresponding one of said at least one condition;
a micro-controller in communication with said signal converter to access said at least one digital value; and
a trip module operably connected to said contacts, said trip module separating said contacts in response to a trip signal generated by an output of said micro-controller;
said micro-controller including non-volatile memory for storing micro-controller firmware and a communications port;
said microcontroller being programmed and configured to receive new firmware from a remote location via said communications port and replace said firm ware stored in said non-volatile memory.

8. The circuit breaker of claim 7 wherein said remote location comprises a host controller, and said host controller is connected to said communications port via a local area network.

9. The circuit breaker of claim 8 wherein said host controller is programmed for monitoring said trip unit.

10. The circuit breaker of claim 8 wherein said host controller is connected via an Internet connection to a remote computer such that said remote computer is capable of monitoring said trip unit.

11. The circuit breaker of claim 8 wherein said host controller is programmed to download firmware to said trip unit.

12. The circuit breaker of claim 8 wherein said host controller is connected via an Internet connection to a remote computer such that said remote computer is capable of downloading firmware to said trip unit.

13. A method of changing firmware in a trip unit which comprises:
at least one sensor for sensing at least one condition of a power line providing electricity to a load;
a signal converter for converting signals generated by said sensors into at least one digital value indicative of said at least one condition;
a micro-controller adapted to access said at least one digital value; and
a trip module for separating separable contacts connected in series on said power line, said trip module responsive to a trip signal generated by an output of said micro-controller;
said micro-controller including non-volatile memory for storing micro-controller firmware and a communications port;
said method comprising the step of downloading new firmware into said non-volatile memory of said micro-controller via said communications port from a remote location.

14. The method set forth in claim 13 wherein said step of downloading new firmware comprises transmitting said new firmware over a local area network to said trip unit.

15. The method set forth in claim 13 wherein said step of downloading new firmware comprises transmitting said new firmware over an Internet connection from said remote location to said trip unit.

16. A method of changing firmware in a circuit breaker which comprises:
a set of contacts for making and breaking an electrical connection between an electrical load and an electrical power supply and a
trip unit comprising:
at least one sensor for generating a signal representative at least one condition of a load;
a signal converter converting each of said at least one signal into a corresponding digital value representing a corresponding one of said at least one condition;
a micro-controller in communication with said signal converter to access said at least one digital value; and
a trip module operably connected to said contacts, said trip module separating said contacts in response to a trip signal generated by an output of said micro-controller;
said micro-controller including non-volatile memory for storing micro-controller firmware and a communications port;
said method comprising the step of downloading new firmware into said non-volatile memory of said micro-controller via said communications port from a remote location.

17. The method according to claim 16 wherein said step of downloading new firmware comprises transmitting said new firmware over a local area network to said trip unit.

18. The method set forth in claim 16 wherein said step of downloading new firmware comprises transmitting said new firmware over an Internet connection from said remote location to said trip unit.
